(19) United States
(12) Patent Application Publication
(10) Pub. No.: US 2002/0075989 A1
(43) Pub. Date: Jun. 20, 2002

(54) High-speed counter with sequential binary count order and method thereof

(75) Inventor: Ki-mo Joo, Seoul (KR)

Correspondence Address: Steven M. Mills, MILLS & ONELLO LLP, Suite 605, Eleven Beacon Street, Boston, MA, 02108, US

(73) Assignee: Samsung Electronics Co., Ltd.

(21) Appl. No.: 09/994,491

(22) Filed: Nov. 26, 2001

(30) Foreign Application Priority Data
Dec. 19, 2000 (KR) 00-78545

(51) Int. Cl. H03K 21/00

(52) U.S. Cl. 377/33

(57) ABSTRACT

A counter circuit, which is capable of operating at high speed and realizing a sequential binary count order, and a counting method thereof are provided. The counter circuit includes a first bit generation circuit, a second bit generation circuit, a third bit generation circuit, and a fourth bit generation circuit. The first bit generation circuit includes a D-flip-flop, inverts its output value every cycle of the clock signal, and generates a first bit output. The second bit generation circuit includes two D-flip-flops, inverts its output value every two cycles of the clock signal, and generates a second bit output. The third bit generation circuit includes four D-flip-flops, inverts its output value every four cycles of the clock signal, and generates a third bit output. The fourth bit generation circuit includes eight D-flip-flops, inverts its output value every eight cycles of the clock signal, and generates a fourth bit output. According to the counter circuit, bit outputs are generated with almost the same delay time within one cycle of a clock signal in a sequential binary count order. Thus, the operation of a system can be prevented from being delayed, and the performance of the system can be improved.

### BACKGROUND OF THE INVENTION

1. Field of the Invention

The present invention relates to a semiconductor integrated circuit, and more particularly, to a counter which is capable of operating at high speed and realizing a sequential binary count order, and a counting method thereof.

2. Description of the Related Art

A counter is a register which outputs data following a predetermined order in response to an input pulse and is widely used in digital logic. In general, counters can be of two basic types, namely, synchronization counters and non-synchronization counters. The non-synchronization counter is called a ripple counter because it includes successive flip-flops each receiving an output signal of a previous flip-flop through its input port in a ripple-like fashion.

FIG. 1 is a diagram illustrating a conventional synchronization counter circuit. A synchronization counter circuit 100 is comprised of a 4-bit counter. The synchronization counter circuit 100 includes flip-flops 101, 102, 103, and 104, and a combination logic unit 110 which includes first and second adders 105 and 106 and an XNOR gate 107. The T-flip-flop 101 is toggled by a clock signal CK and outputs a signal as a bit output OUT<0> to the first adder 105. The first D-flip-flop 102 and the third D-flip-flop 104 output a bit output OUT<1> and a bit output OUT<3>, respectively, in accordance with the operation of the first adder 105, which receives the bit output OUT<0>, and the operation of the second adder 106, which receives a carry value of the first adder 105. The second D-flip-flop 103 outputs a bit output OUT<2> in accordance with the output of the XNOR gate 107 which receives a carry value of the second adder 106.

FIG. 2 shows the waveform of each of the bit outputs OUT<0> through OUT<3> varying in accordance with the operation of the synchronization counter circuit 100. In FIG. 2, the frequency of the clock signal CK is set at 1 Ghz, and the bit outputs OUT<0> through OUT<3> are sequentially toggled by the clock signal CK, thus increasing a bit counter. As shown in the waveform of the bit output OUT<3>, the starting point of the bit output <3> is delayed relative to the starting point of the clock signal CK by as much as 11 ns due to delay of the combination logic unit 110. The fact that the bit output <3> is delayed relative to the clock signal CK puts restrictions on determination of a maximum operation frequency of the synchronization counter circuit 100. As a result of simulation performed under predetermined conditions, it can be found that the operation frequency of the synchronization counter circuit 100 is limited to 1 GHz.

FIG. 3 is a diagram illustrating a conventional non-synchronization counter circuit. A non-synchronization counter circuit 300 includes a plurality of D-flip-flops 301, 302, 303, and 304. The first D-flip-flop 301 is synchronized with a clock signal CK and inputs its inverted output QB. Next, an output port Q of the first D-flip-flop 301 is connected to a clock signal port CK of the second D-flip-flop, an inverted output port QB of the second D-flip-flop 302 is connected to an input data port D of the second D-flip-flop 302. Input and output ports of the third and fourth D-flip-flops 303 and 304 are connected to each other in the same way as those of the first and second D-flip-flops 301 and 302. The output ports Q of the first through fourth D-flip-flops 301 through 304 output bit outputs OUT<0> through OUT<3>, respectively, of the non-synchronization counter circuit 300.

FIG. 4 is a timing diagram illustrating the operation of the non-synchronization counter circuit 300. Referring to FIG. 4, the frequency of the clock signal CK is set at 2 Ghz, and the bit outputs OUT<0> through OUT<3> are sequentially output in accordance with the clock signal CK, increasing a bit counter. FIG. 5 is an enlarged view of a part A shown in FIG. 4, which includes a, predetermined portion of each graph showing the waveforms of the bit outputs OUT<0> through OUT<3>. As shown in FIG. 5, the clock signal CK has a cycle of 0.5 ns. Among the bit outputs OUT<0> through OUT<3> that are sequentially output in response to the clock signal CK, the bit output OUT<3>, which is the most significant bit (MSB), is output one cycle of the clock signal CK or more past the starting point of the clock signal CK. Since the state of the non-synchronization counter circuit 300 is ultimately dependent on the state of the MSB and operation of a system is also directly connected to the state of the MSB, the operation of the system may be caused to be delayed for a long time.

FIG. 6 is a diagram illustrating a Johnson's counter circuit developed to overcome the problems with the conventional synchronization counter circuit 100 shown in FIG. 1 and the conventional non-synchronization counter circuit 300 shown in FIG. 3. Referring to FIG. 6, a Johnson's counter circuit 600 includes first through fourth D-flip-flops 601 through 604. A clock signal CK is simultaneously input to the first through fourth D-flip-flops 601 through 604. An output port Q of the first D-flopflop 601 is connected to a data input port D of the second D-flip-flop 602, an output port Q of the second D-flip-flop 602 is connected to a data input port D of the third D-flip-flop 603, an output port Q of the third D-flip-flop 603 is connected to a data input port D of the fourth D-flip-flop 604, and an inverted data port QB of the fourth D-flip-flop 604 is connected to the data input port D of the first flip-flop 601. The outputs (or output signals) of the first through fourth D-flip-flops 601 through 604 become bit outputs OUT<0> through OUT<3>, respectively, of the Johnson's counter circuit 600.

FIG. 7 is a diagram illustrating a count order of the Johnson's counter circuit 600. In the count order shown in FIG. 7, bit outputs appear in the order of 0000, 1000, 1100, 1110, 1111, 0111, 0011, 0001, 0000, . . . . However, the Johnson's counter circuit 600 needs a combination apparatus to organize the bit outputs into a sequential binary count order, in which bit outputs appear in the order of 0000, 0001, 0010, 0011, 0100, 0101, . . . . The sequential binary count order can be used to determine how many bit outputs are ahead of a selected bit output, that is, where the selected bit output stands in the order of all bit outputs. Accordingly, the sequential binary count order is convenient for the operation of a system. The Johnson's counter circuit 600 has an operational frequency higher than that of the synchronization and non-synchronization counter circuits 100 and 300; however, it needs an additional combination apparatus. Therefore, it is required to develop a counter circuit which is capable of operating at high speed and realizing a sequential binary count order.

### SUMMARY OF THE INVENTION

To solve the above-described problems, it is a first object of the present invention to provide a counter circuit which is capable of operating at high speed and realizing a sequential binary count order.

It is a second object of the present invention to provide a counting method of the counter circuit.

Accordingly, to achieve the first object, there is provided a counter circuit, which is capable of realizing a sequential binary count order. The counter circuit includes a first bit generation circuit which inverts its output value every cycle of a clock signal in response to the clock signal and generates the inverted output value as a first bit output, a second bit generation circuit which inverts its output value every two cycles of the clock signal in response to the clock signal and generates the inverted output value as a second bit output, a third bit generation circuit which inverts its output value every four cycles of the clock signal in response to the clock signal and generates the inverted output value as a third bit output, and a fourth bit generation circuit which inverts its output value every eight cycles of the clock signal in response to the clock signal and generates the inverted output value as a fourth bit output.

In one embodiment, the first through fourth bit generation circuits each include as many D-flip-flops as the number of bits repeated in their respective bit output. The first bit generation circuit comprises a D-flip-flop including a clock signal port to which the clock signal is input, a data port to which the inverted output value of the first generation circuit is input, and an output port which outputs the first bit output. The second bit generation circuit can include a first D-flip-flop having a clock signal port to which the clock signal is input and a data port to which an inverted output of the second bit output is input and a second D-flip-flop having a clock signal port to which the clock signal is input, a data port to which the output of the first D-flip-flop is input, and an output port which outputs the second bit output.

The third bit generation circuit can include a first D-flip-flop which includes a clock signal port to which the clock signal is input and a data port to which an inverted output of the third bit output is input, a second D-flip-flop having a clock signal port to which the clock signal is input and a data port to which the output of the first D-flip-flop is input, a third D-flip-flop having a clock signal port to which the clock signal is input and a data port to which the output of the second D-flip-flop is input, and a fourth D-flip-flop having a clock signal port to which the clock signal is input, a data port to which the output of the third D-flip-flop is input and an output port which outputs the third bit output.

The fourth bit generation circuit can include a first D-flip-flop having a clock signal port to which the clock signal is input and a data port to which an inverted output of the fourth bit output is input, a second D-flip-flop having a clock signal port to which the clock signal is input and a data port to which the output of the first D-flip-flop is input, a third D-flip-flop having a clock signal port to which the clock signal is input and a data port to which the output of the second D-flip-flop is input, a fourth D-flip-flop having a clock signal port to which the clock signal is input and a data port to which the output of the third D-flip-flop is input, a fifth D-flip-flop having a clock signal port to which the clock signal is input and a data port to which the output of the fourth D-flip-flop is input, a sixth D-flip-flop having a clock signal port to which the clock signal is input and a data port to which the output of the fifth D-flip-flop is input, a seventh D-flip-flop having a clock signal port to which the clock signal is input and a data port to which the output of the sixth D-flip-flop is input, and an eighth D-flip-flop having a clock signal port to which the clock signal is input, a data port to which the output of the seventh D-flip-flop is input, and an output port which outputs the fourth bit output.

The first through fourth bit generation circuits may be each comprised of a register, which stores their respective bit output in response to the clock signal, instead of the D-flip-flops.

To achieve the second object, there is provided a counting method, which can realize a sequential binary count order. The counting method includes inverting a first bit output every cycle of a clock signal in response to the clock signal and generating the inverted first bit output as the first bit output, inverting a second bit output every two cycles of the clock signal in response to the clock signal and generating the inverted second bit output as the second bit output, inverting a third bit output every four cycles of the clock signal in response to the clock signal and generating the inverted third bit output as the third bit output, and inverting a fourth bit output every eight cycles of the clock signal in response to the clock signal and generating the inverted fourth bit output as the fourth bit output.

According to the present invention, bit outputs are output with almost the same delay time within one cycle of a clock signal in a sequential binary count order. Thus, the operation of a system can be prevented from being delayed, and the performance of the system can be improved.

### BRIEF DESCRIPTION OF THE DRAWINGS

The foregoing and other objects, features and advantages of the invention will be apparent from the more particular description of a preferred embodiment of the invention, as illustrated in the accompanying drawings in which like reference characters refer to the same parts throughout the different views. The drawings are not necessarily to scale, emphasis instead being placed upon illustrating the principles of the invention.

FIG. 1 is a diagram illustrating a conventional synchronization counter circuit.

FIG. 2 is a diagram illustrating waveforms of the operation of the synchronization counter circuit of FIG. 1.

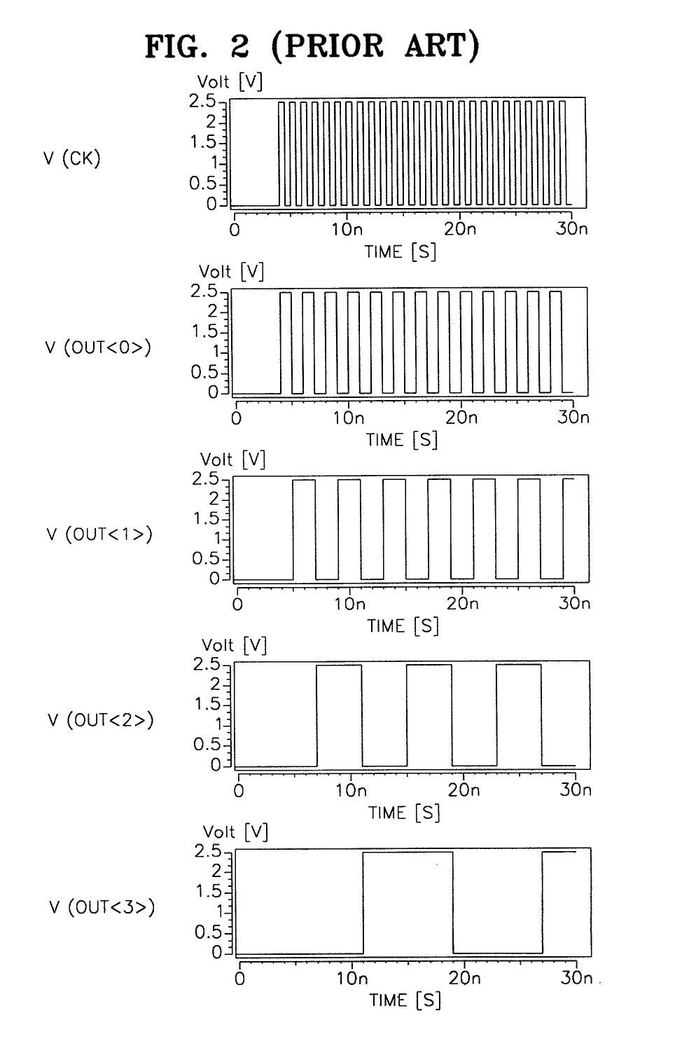

FIG. 3 is a diagram illustrating a conventional non-synchronization counter circuit.

FIG. 4 is a diagram illustrating waveforms of the operation of the non-synchronization counter circuit of FIG. 3.

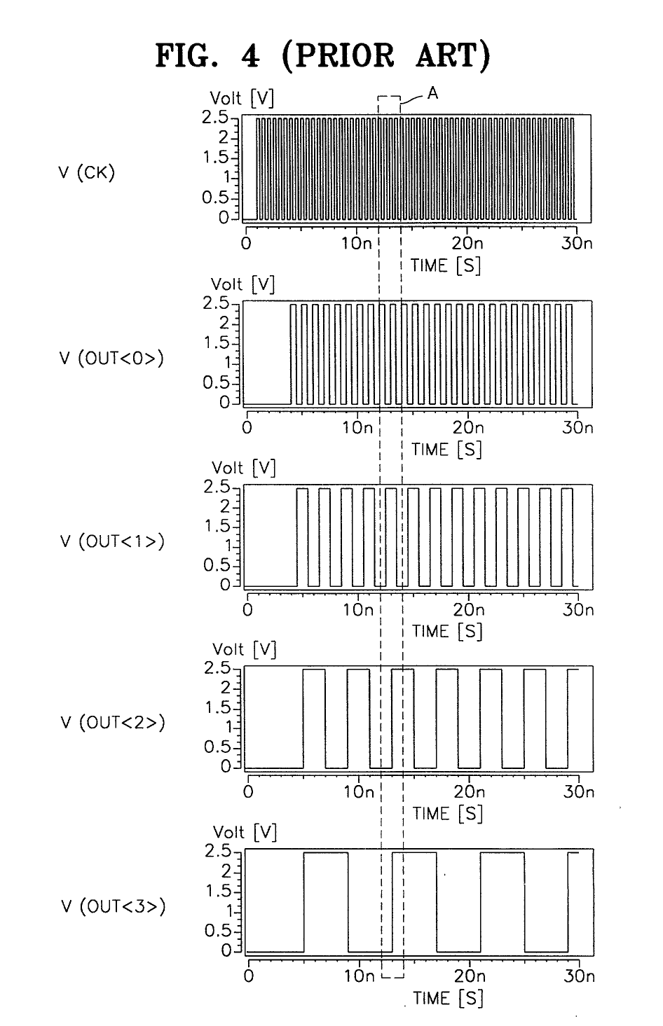

FIG. 5 is an enlarged view of a part A shown in FIG. 4.

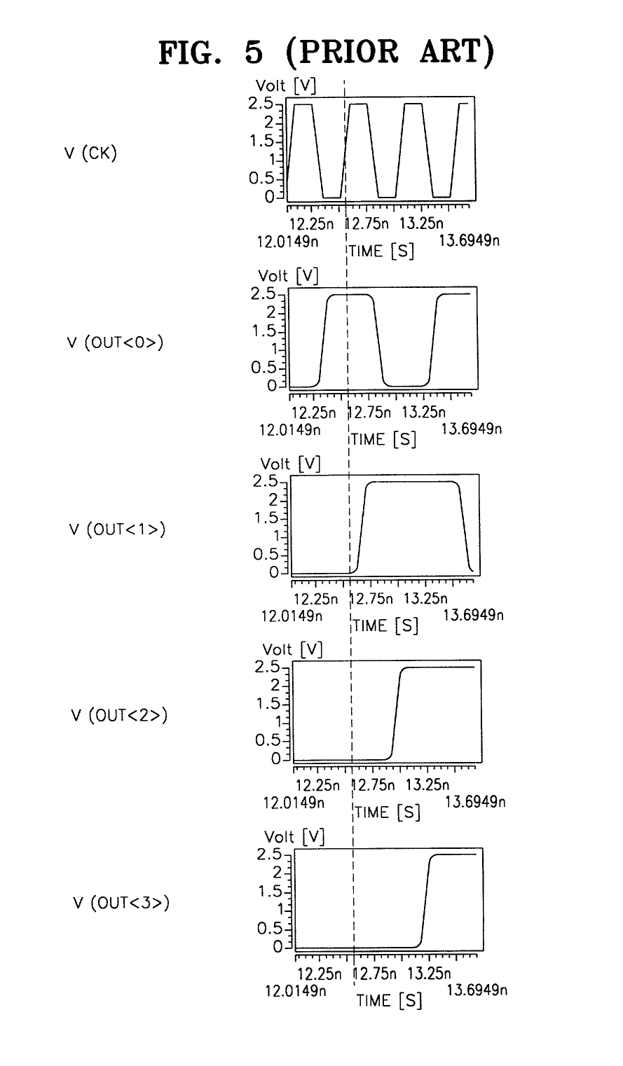

FIG. 6 is a diagram illustrating a Johnson's counter circuit.

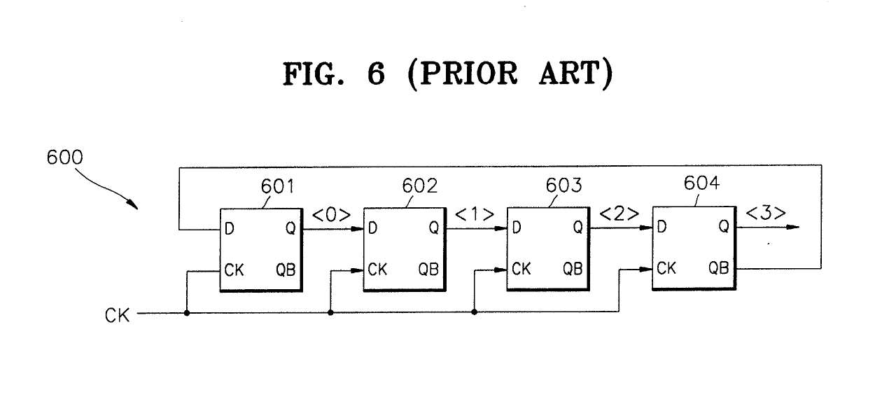

FIG. 7 is a diagram illustrating a count order of the Johnson's counter circuit of FIG. 6.

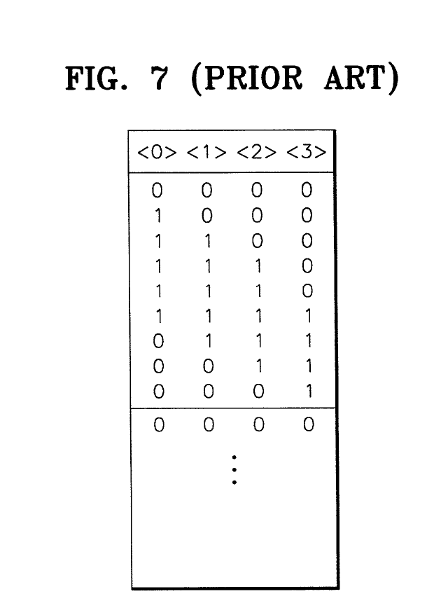

FIG. 8 is a diagram illustrating one embodiment of a counter circuit according to the present invention.

FIG. 9 is a diagram illustrating a sequential binary count order.

FIG. 10 is a diagram illustrating waveforms of the operation of the counter circuit of FIG. 8.

FIG. 11 is an enlarged view of a part B shown in FIG. 10.

### DETAILED DESCRIPTION OF PREFERRED EMBODIMENTS OF THE INVENTION

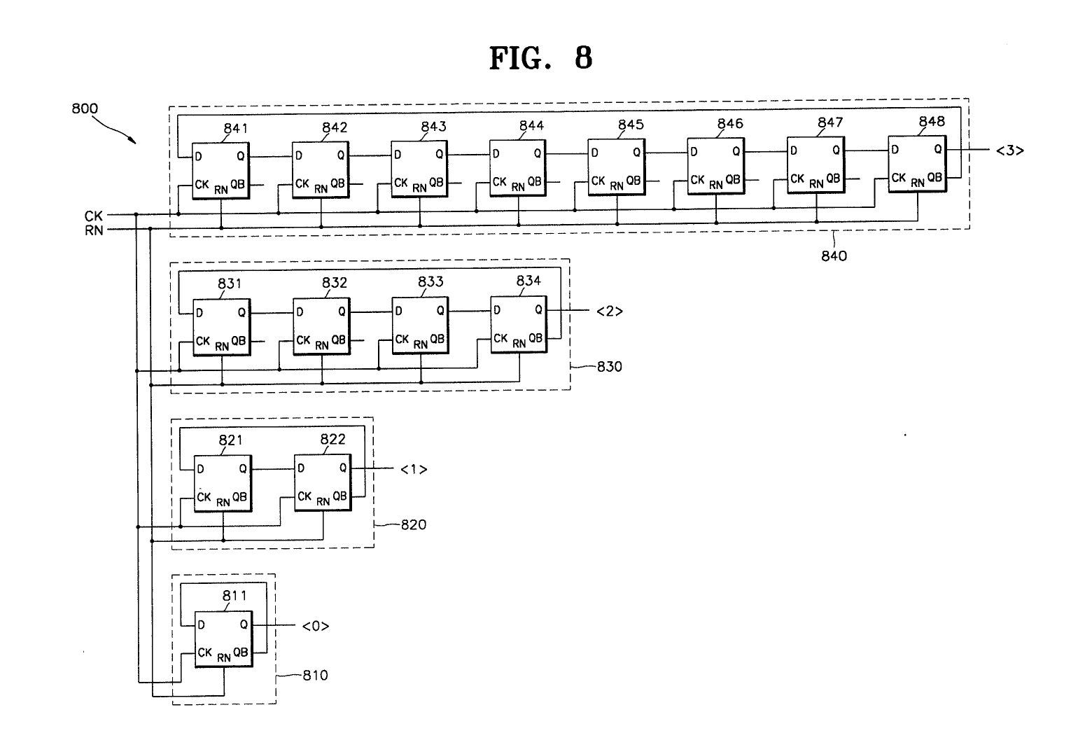

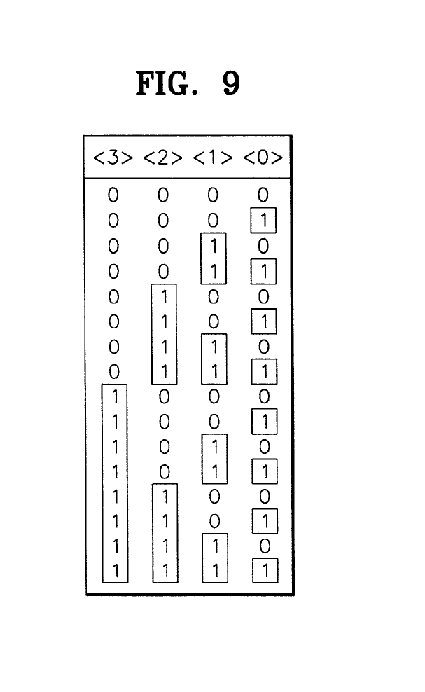

FIG. 8 is a diagram illustrating a counter circuit according to the present invention. Referring to FIG. 8, the counter circuit 800, which is capable of realizing a sequential binary count order, includes a first bit generation circuit 810, a second bit generation circuit 820, a third bit generation circuit 830, and a fourth bit generation circuit 840. The initial output value of each of the first through fourth bit generation circuits 810 through 840 is reset to 0 by a reset signal RN, and then the first through fourth bit generation circuits 810 through 840 operate following a sequential binary count order shown in FIG. 9. As shown in FIG. 9, bit outputs <0:3> are output in the order 0000, 0001, 0010, 0011, . . . . Specifically, a bit <0> is output in the order 0, 1, 0, 1, . . . ; bit <1> is output in the order 0, 0, 1, 1, 0, 0, 1, 1, . . . ; bit <2> is output in the order 0, 0, 0, 0, 1, 1, 1, 1, 0, 0, 0, 0, . . . ; and bit <3> is output in the order 0, 0, 0, 0, 0, 0, 0, 0, 1, 1, 1, 1, 1, 1, 1, 1, 0, 0, 0, 0, 0, 0, 0, 0, . . . .

In FIG. 8, the first bit generation circuit 810 makes the output value of the bit <0> vary every one bit, the second bit generation circuit 820 makes the output value of the bit <1> vary every two bits, the third bit generation circuit 830 makes the output value of the bit <2> vary every four bits, and the fourth bit generation circuit 840 makes the output value of the bit <3> vary every eight bits. The first bit generation circuit 810 includes one D-flip-flop 811. An inverted output QB of the D-flip-flop 811 is input to a data port D in response to a clock signal CK. An output Q of the first bit generation circuit 810 becomes the output bit <0>. The output value of the bit <0> is varied every cycle of the clock signal CK and is stored. Thus, as shown in FIG. 9, the bit <0> is output in the order 0, 1, 0, 1, . . . .

The second bit generation circuit 820 includes a first D-flip-flop 821 and a second D-flip-flop 822. In response to the clock signal CK, an inverted output QB of the second D-flip-flop 822 is input to a data port D of the first D-flip-flop 821, and an output Q of the first flip-flop 821 is input to a data port D of the second D-flip-flop 822. Finally, an output Q of the second flip-flop 822 is the output bit <1>. The output value of the bit <1> is varied every two cycles of the clock signal CK and is stored. Accordingly, the bit <1> is output every cycle of the clock signal CK in the order 0, 0, 1, 1, 0, 0, 1, 1, . . . .

The third bit generation circuit 830 includes four D-flip-flops 831, 832, 833, and 834. In response to the clock signal CK, an inverted output QB of the fourth flip-flop 834 is input to a data port of the first D-flip-flop 831, an output Q of the first flip-flop 831 is input to a data port D of the second flip-flop 832, an output Q of the second flip-flop 832 is input to a data port D of the third flip-flop 833, and an output Q of the third flip-flop 833 is input to a data port of the fourth D-flip-flop 834. Finally, an output Q of the fourth flip-flop 834 is the output bit <2>. The output value of the bit <2> is varied every four cycles of the clock signal CK and is stored. Accordingly, the bit <2> is output every cycle of the clock signal CK in the order 0, 0, 0, 0, 1, 1, 1, 1, 0, 0, 0, 0, . . . .

The fourth bit generation circuit 840 includes eight D-flip-flops 841, 842, . . . , and 848. In response to the clock signal CK, an inverted output QB of the eighth D-flip-flop 848 is input to a data port D of the first D-flip-flop 841, an output Q of the first flip-flop 841 is input to a data port D of the second D-flip-flop 842, an output Q of the second D-flip-flop 842 is input to a data port D of the third D-flip-flop 843, an output Q of the third D-flip-flop 843 is input to a data port D of the fourth D-flip-flop 844, an output Q of the fourth D-flip-flop 844 is input to a data port D of the fifth D-flip-flop 845, an output Q of the fifth D-flip-flop 845 is input to a data port D of the sixth D-flip-flop 846, an output Q of the sixth D-flip-flop 846 is input to a data port D of the seventh D-flip-flop 847, and an output Q of the seventh D-flip-flop 847 is input to a data port D of the eighth D-flip-flop 848. Finally, an output Q of the eighth D-flip-flop 848 becomes the output bit <3>. The output value of the bit <3> is varied every eight cycles of the clock signal CK and is stored. The bit <3> is output every cycle of the clock signal CK in the order 0, 0, 0, 0, 0, 0, 0, 0, 1, 1, 1, 1, 1, 1, 1, 1, 0, 0, 0, 0, 0, 0, 0, 0, . . . .

Accordingly, the first through fourth bit generation circuits 810, 820, 830, and 840 generate bit outputs which can satisfy a sequential binary count order.

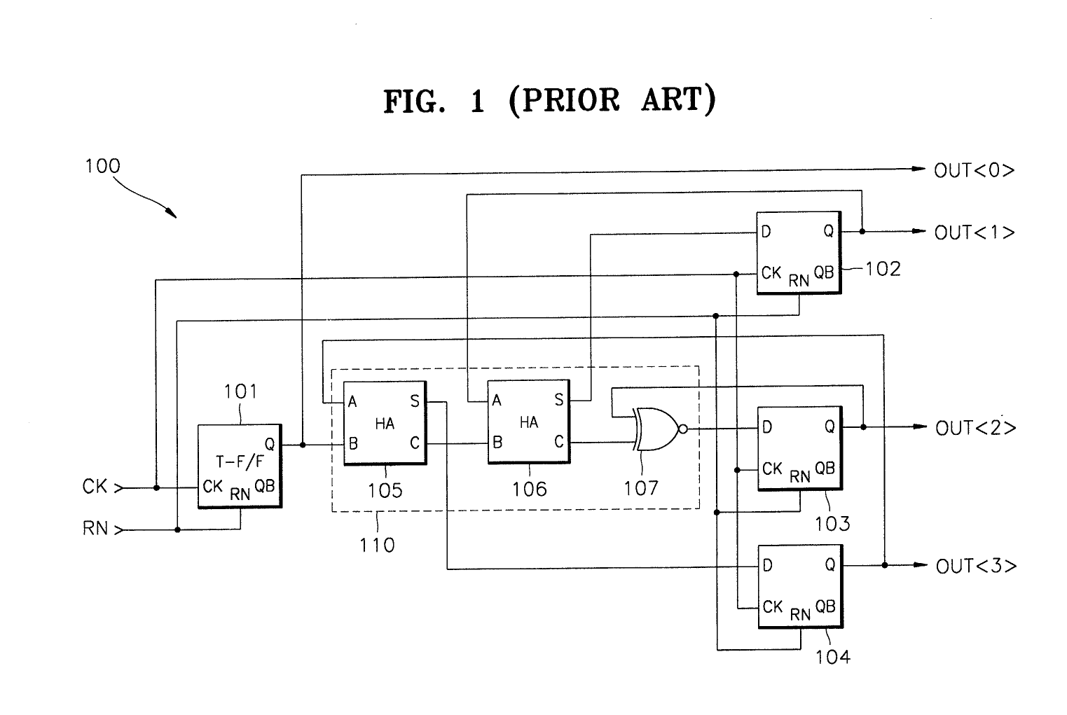

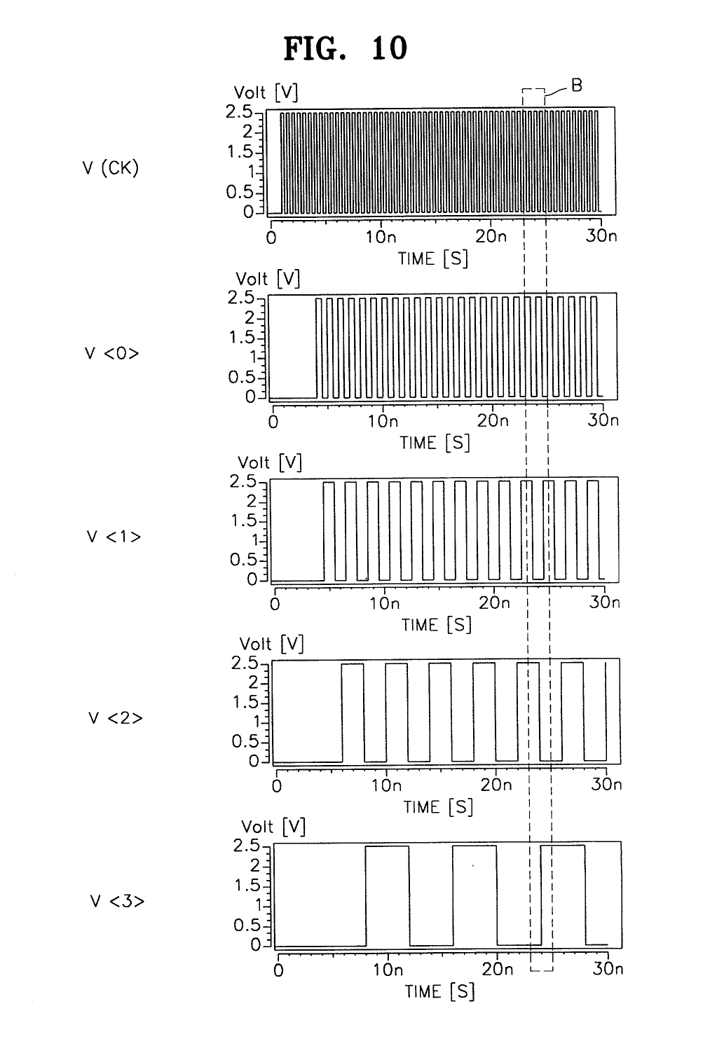

FIG. 10 is a diagram illustrating waveforms of the operation of the counter circuit 800 shown in FIG. 8. The frequency of the clock signal CK is set at 2 GHz, and bit outputs <0:3> are sequentially output in response to the clock signal CK, increasing a bit counter. In the waveform of bit <3>, the starting point of the output of bit <3> is delayed with respect to the starting point of the clock signal CK by as much as 8 ns. The output of bit <3> is delayed relative to the clock signal CK by as much as 3 ns less than the bit output OUT<3> of the conventional synchronization counter circuit 100 shown in FIG. 1.

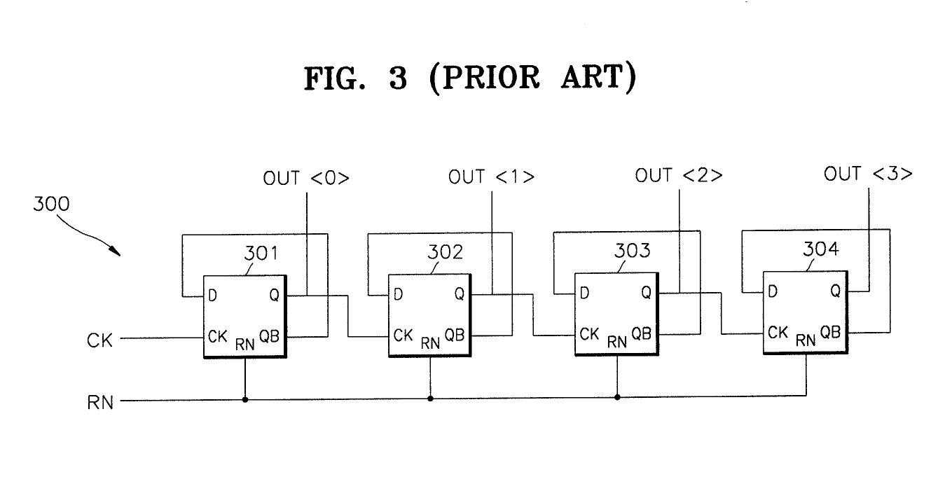

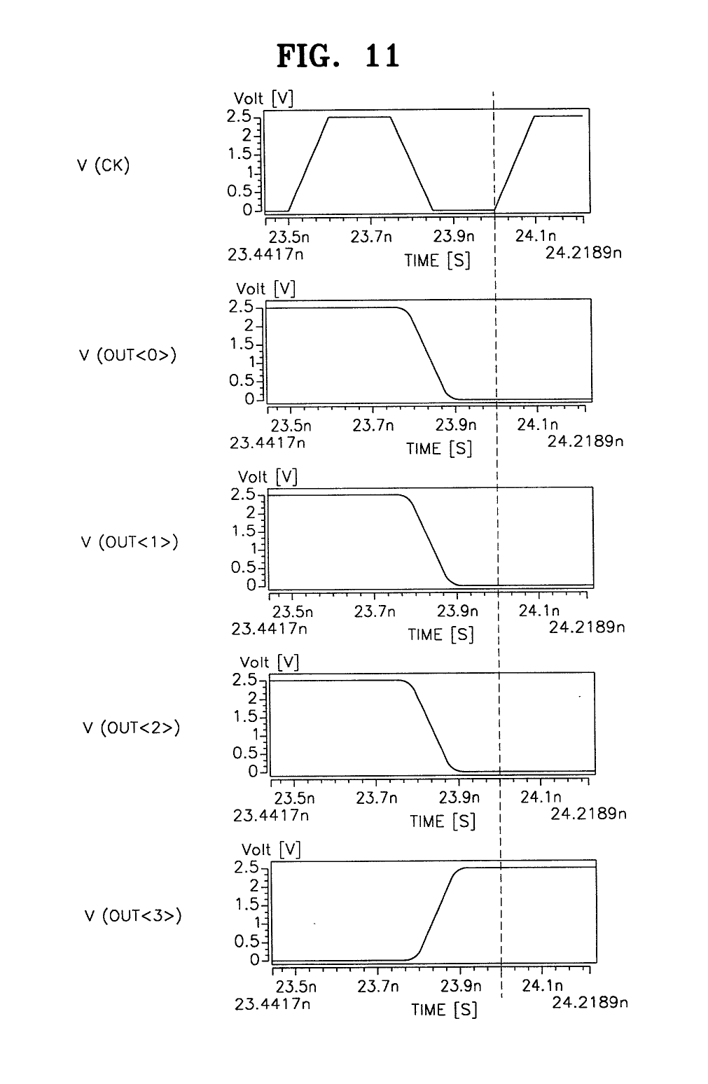

FIG. 11 is an enlarged view of a part B shown in FIG. 10. Referring to FIG. 11, the bit outputs <0:3>, which are sequentially generated in response to the clock signal CK having a cycle of 0.5 ns, are output within one cycle of the clock signal CK from the starting point of the clock signal CK. In the conventional non-synchronization counter circuit 300 of FIG. 3, the fourth bit output OUT<3> that is the most significant bit (MSB) is output one cycle of the clock signal CK or more past the starting point of the clock signal CK, and thus the operation of a system is considerably delayed. However, in the counter circuit 800 of the present invention, the bit outputs <0:3> are output with almost the same delay time within one cycle of the clock signal CK. Thus, the operation of a system can be prevented from being delayed, and the performance of the system can be improved.

While this invention has been particularly shown and described with reference to preferred embodiments thereof, it will be understood by those skilled in the art that various changes in form and details may be made therein without departing from the spirit and scope of the invention as defined by the appended claims. For example, in the specification, only a four-bit counter circuit has been described as an example of the present invention; however, the present invention can be applied to various counter circuits having different numbers of bits. In addition, each bit generation circuit has been described above as including as many D-flip-flops as the number of bits repeated in a predetermined bit output; however, a register, which can store data in response to a clock signal, may be used instead of the D-flip-flops.

According to the counter circuit of the present invention, bit outputs are output with almost the same delay time within one cycle of a clock signal in a sequential binary count order. Thus, the operation of a system can be prevented from being delayed, and the performance of the system can be improved.

What is claimed is:

1. A counter circuit with a sequential binary count order, the counter circuit comprising:
a first bit generation circuit which inverts its output value every cycle of a clock signal in response to the clock signal and generates the inverted output value as a first bit output;
a second bit generation circuit which inverts its output value every two cycles of the clock signal in response to the clock signal and generates the inverted output value as a second bit output;
a third bit generation circuit which inverts its output value every four cycles of the clock signal in response to the clock signal and generates the inverted output value as a third bit output; and
a fourth bit generation circuit which inverts its output value every eight cycles of the clock signal in response to the clock signal and generates the inverted output value as a fourth bit output.

2. The counter circuit of claim 1, wherein the first bit generation circuit comprises a D-flip-flop, the D flip-flop comprising:
a clock signal port to which the clock signal is input,
a data port to which the inverted output value of the first generation circuit is input, and
an output port which outputs the first bit output.

3. The counter circuit of claim 1, wherein the first bit generation circuit comprises a register which stores the first bit output in response to the clock signal.

4. The counter circuit of claim 1, wherein the second bit generation circuit comprises:
a first D-flip-flop which includes a clock signal port to which the clock signal is input and a data port to which an inverted output of the second bit output is input; and
a second D-flip-flop which includes a clock signal port to which the clock signal is input, a data port to which the output of the first D-flip-flop is input, and an output port which outputs the second bit output.

5. The counter circuit of claim 1, wherein the second bit generation circuit comprises a register which stores the second bit output in response to the clock signal.

6. The counter circuit of claim 1, wherein the third bit generation circuit comprises:
a first D-flip-flop which includes a clock signal port to which the clock signal is input and a data port to which an inverted output of the third bit output is input;
a second D-flip-flop which includes a clock signal port to which the clock signal is input and a data port to which the output of the first D-flip-flop is input;
a third D-flip-flop which includes a clock signal port to which the clock signal is input and a data port to which the output of the second D-flip-flop is input; and
a fourth D-flip-flop which includes a clock signal port to which the clock signal is input, a data port to which the output of the third D-flip-flop is input, and an output port which outputs the third bit output.

7. The counter circuit of claim 1, wherein the third bit generation circuit comprises a register which stores the third bit output in response to the clock signal.

8. The counter circuit of claim 1, wherein the fourth bit generation circuit comprises:
a first D-flip-flop which includes a clock signal port to which the clock signal is input and a data port to which an inverted output of the fourth bit output is input;
a second D-flip-flop which includes a clock signal port to which the clock signal is input and a data port to which the output of the first D-flip-flop is input;
a third D-flip-flop which includes a clock signal port to which the clock signal is input and a data port to which the output of the second D-flip-flop is input;
a fourth D-flip-flop which includes a clock signal port to which the clock signal is input and a data port to which the output of the third D-flip-flop is input;
a fifth D-flip-flop which includes a clock signal port to which the clock signal is input and a data port to which the output of the fourth D-flip-flop is input;
a sixth D-flip-flop which includes a clock signal port to which the clock signal is input and a data port to which the output of the fifth D-flip-flop is input;
a seventh D-flip-flop which includes a clock signal port to which the clock signal is input and a data port to which the output of the sixth D-flip-flop is input; and
a eighth D-flip-flop which includes a clock signal port to which the clock signal is input, a data port to which the output of the seventh D-flip-flop is input, and an output port which outputs the fourth bit output.

9. The counter circuit of claim 1, wherein the fourth bit generation circuit comprises a register which stores the fourth bit output in response to the clock signal.

10. A counting method with a sequential binary count order, the counting method comprising:
inverting a first bit output every cycle of a clock signal in response to the clock signal and generating the inverted first bit output as the first bit output;
inverting a second bit output every two cycles of the clock signal in response to the clock signal and generating the inverted second bit output as the second bit output;
inverting a third bit output every four cycles of the clock signal in response to the clock signal and generating the inverted third bit output as the third bit output; and
inverting a fourth bit output every eight cycles of the clock signal in response to the clock signal and generating the inverted fourth bit output as the fourth bit output.
